(19) United States
(12) Patent Application Publication
(10) Pub. No.: US 2024/0271996 A1
(43) Pub. Date: Aug. 15, 2024

(54) OPTICAL BEAM SENSOR WITH CENTER TRANSMISSIVE CUT-OUT

(71) Applicant: KLA Corporation, Milpitas, CA (US)

(72) Inventors: Matthew Hoffman, Los Altos, CA (US); Florian Melsheimer, Cologne (DE); Alon Rosenthal, Weston, CT (US)

(21) Appl. No.: 18/408,395

(22) Filed: Jan. 9, 2024

Related U.S. Application Data
(60) Provisional application No. 63/444,246, filed on Feb. 9, 2023.

(51) Int. Cl. G01J 1/42; G01N 21/88; G03F 7/00; G03F 7/20

(52) U.S. Cl. CPC G01J 1/4257; G01J 1/429; G01N 21/8806; G03F 7/2039; G03F 7/70033; G03F 7/7055; G03F 7/706; G03F 7/706851

(57) ABSTRACT

Methods and systems for determining one or more characteristics of light in an optical system are provided. One system includes a detector positioned in a path of light between a light source in the optical system and a specimen for which the optical system performs a process. The detector includes a center cut-out configured to allow only a first portion of the light from the light source to pass therethrough and four or more detector segments positioned around the center cut-out and in a path of only a second portion of the light from the light source. The four or more detector segments are configured to separately generate output responsive to the light incident thereon. The system also includes a control subsystem configured for determining one or more characteristics of the light from the light source based on the output separately generated by the four or more detector segments.

### BACKGROUND OF THE INVENTION

### 1. Field of the Invention

This invention generally relates to methods and systems for determining one or more characteristics of light in an optical system.

### 2. Description of the Related Art

The following description and examples are not admitted to be prior art by virtue of their inclusion in this section.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a photomask to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

With the performance of 193 nm immersion lithography reaching its limit as well as the substantially high cost and yield issues associated with multi-patterning lithography processes, extreme ultraviolet (EUV) lithography has been under extensive development and is used for next generation lithography (NGL) technology to extend Moore's law, driving computer chips to be smaller, faster, and more efficient.

Defectivity control of EUV photomasks, which define the patterns printed on wafers, plays a critical role from a process yield management perspective. However, it has been regarded as one of the high risk areas of EUV lithography development due to the lack of actinic EUV photomask or high throughput charged particle beam inspection tools that can inspect the photomask at the necessary resolution. Although there are a few products now on the market that provide relatively high speed actinic EUV patterned mask inspection, these inspectors are relatively complex for a number of reasons that are not a factor in mask inspection at longer wavelengths.

The geometries on EUV masks require inspection systems with relatively high image fidelity and substantially low detection noise to resolve the defect features that can cause performance degradation of the integrated circuits fabricated from these masks in EUV lithography. The EUV spectral range, however, presents many new challenges to the optical and system design of an inspection tool due to the short wavelength, energetic photons, and low radiance (brightness) of laboratory (i.e., relatively compact) EUV radiation sources. The precise knowledge of spatial incident intensity distribution within the illumination field at the mask is essential for image analysis in the inspection tool.

Traditional beam stabilization systems utilize beam splitters that intersect the entre cross-section of the beam to split a portion of the light to an optical detector (e.g., a quad-cell detector, but position sensitive detectors and cameras can also be used). Typically, a separate tooling camera or other imaging device is required to evaluate beam shape.

A primary disadvantage of prior methods is that they require beam splitters to redirect a portion of the beam to a detector. For wavelengths such as EUV (e.g., 13.5 nm) for which efficient beam splitters do not yet exist, this would result in significant attenuation of the primary beam, which is unacceptable for many applications such as high-speed imaging inspection.

Another disadvantage of prior methods is that they require additional sensors, opto-mechanics, and tooling to evaluate beam profile. Such additional hardware adds cost, complexity, and contamination risks for ultra-clean systems and introduces the same problems noted above if beam splitters are used to sample the main beam. As an alternative to beam splitters, prior applications have also shuttled a detector into and out of the primary beam for direct sampling. This approach has the disadvantage of requiring additional actuators and mechanisms and of blocking the beam entirely such that measurements cannot be made in-situ while the system is fully-operational.

Accordingly, it would be advantageous to develop systems and/or methods for determining one or more characteristics of light in an optical system that do not have one or more of the disadvantages described above.

### SUMMARY OF THE INVENTION

The following description of various embodiments is not to be construed in any way as limiting the subject matter of the appended claims.

One embodiment relates to a system configured for determining one or more characteristics of light in an optical system. The system includes a detector positioned in a path of light between a light source in the optical system and a specimen for which the optical system performs a process. The detector includes a center cut-out configured to allow only a first portion of the light from the light source to pass therethrough. The first portion of the light is directed to the specimen by the optical system during the process. The detector also includes four or more detector segments positioned around the center cut-out and in a path of only a second portion of the light from the light source. The four or more detector segments are configured to separately generate output responsive to the light incident thereon. The system also includes a control subsystem configured for determining one or more characteristics of the light from the light source based on the output separately generated by the four or more detector segments. The system may be further configured as described herein.

Another embodiment relates to a system configured for determining one or more characteristics of light in an optical system. The system includes a light source configured for generating light having one or more wavelengths shorter than 190 nm. The system also includes optical elements configured for directing the light generated by the light source to a specimen and directing the light from the specimen to one or more first detectors configured to generate first output responsive to the light from the specimen. The system further includes a computer subsystem configured for determining information for the specimen based on the first output.

The system also includes a second detector positioned in a path of the light between the light source and the specimen. The second detector includes a center cut-out configured to allow only a first portion of the light from the light source to pass therethrough. The first portion of the light is directed to the specimen by one or more of the optical elements. The second detector also includes four or more detector segments positioned around the center cut-out and in a path of a second portion of the light from the light source. The four or more detector segments are configured to separately generate second output responsive to the light incident thereon. In addition, the system includes a control subsystem configured for determining one or more characteristics of the light from the light source based on the second output and for altering at least one of one or more parameters of the light source, one or more parameters of the optical elements, one or more parameters of the one or more first detectors, and one or more parameters used by the computer subsystem to determine the information based on the determined one or more characteristics. The system may be further configured as described herein.

A further embodiment relates to a computer-implemented method for determining one or more characteristics of light in an optical system. The method includes detecting light in a path between a light source in the optical system and a specimen for which the optical system performs a process. The detecting includes passing only a first portion of the light from the light source through a center cut-out of a detector. The first portion of the light is directed to the specimen by the optical system during the process. The detecting also includes separately generating output responsive to the light incident on four or more detector segments of the detector positioned around the center cut-out and in a path of only a second portion of the light from the light source. The method also includes determining one or more characteristics of the light from the light source based on the output separately generated by the four or more detector segments.

The steps of the method may be performed as described further herein. In addition, the method may include any other step(s) of any other method(s) described herein. The method may be performed by any of the systems described herein.

An additional embodiment relates to a non-transitory computer-readable medium storing program instructions executable on a computer system for performing a computer-implemented method for determining one or more characteristics of light in an optical system. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Other objects and advantages of the invention will become apparent upon reading the following detailed description and upon reference to the accompanying drawings in which:

FIGS. 1 and 3 are schematic diagrams illustrating side views of embodiments of a system configured for determining one or more characteristics of light in an optical system;

FIG. 2 is a schematic diagram illustrating a plan view of an embodiment of a detector that includes a center cut-out configured to allow only a first portion of light from a light source to pass therethrough and four or more detector segments positioned around the center cut-out and in a path of only a second portion of the light from the light source; and

FIG. 4 is a block diagram illustrating one embodiment of a non-transitory computer-readable medium storing program instructions executable on a computer system for performing one or more of the computer-implemented methods described herein.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

The embodiments described herein generally relate to methods and systems for determining one or more characteristics of light in an optical system. The embodiments generally include a multi-cell (e.g., quad-cell, octa-cell, etc.) beam position and/or aberration sensor with a center transmissive cut-out. The described multi-cell detector with center transmissive cut-out is a segmented detector that can advantageously be placed inline with an optical beam for in-situ measurements of beam position and/or shape. A primary purpose of the detector may be to provide servo control feedback for beam stabilization in which an optic, mounted on an actuator, is moved to maintain desired beam pointing based on measured position. This beam position maintenance is traditionally done with quad-cell detectors, but the inclusion of more than four segments (e.g., eight rather than four segments) allows for simultaneous measurement of beam shape, which can serve a number of diagnostic purposes such as guiding upstream optical alignment. Furthermore, the center cut-out allows unattenuated transmission of the primary beam such that only the beam periphery is blocked. This design feature is essential for maximizing power transmission through systems that operate at wavelengths for which efficient beam splitters do not yet exist such as extreme ultraviolet (EUV) (e.g., 13.5 nm).

In one embodiment, the light is EUV light. In another embodiment, the light is vacuum ultraviolet (VUV) light. In a further embodiment, the light is soft x-rays. For example, the light may be EUV light having a wavelength of about 13.5 nm, one or more wavelengths in a range of about 10 nm to about 124 nm, or one or more wavelengths in a range of about 5 nm to about 30 nm, another VUV light having one or more wavelengths less than 190 nm (meaning that the optical system must be operated in a vacuum to prevent the light from being absorbed by the atmosphere), or soft x-rays having a wavelength of about 0.12 nm to about 5 nm. The light source may include any suitable light source known in the art capable of emitting light at one or more of these wavelengths. Such light sources include, but are not limited to, laser-induced plasma sources, discharge-induced plasma sources, cathode/anode type sources, etc. In addition, the embodiments described herein can be used with any light source emitting light that can be used for one or more of the applications described further herein, e.g., inspection, metrology, and defect review.

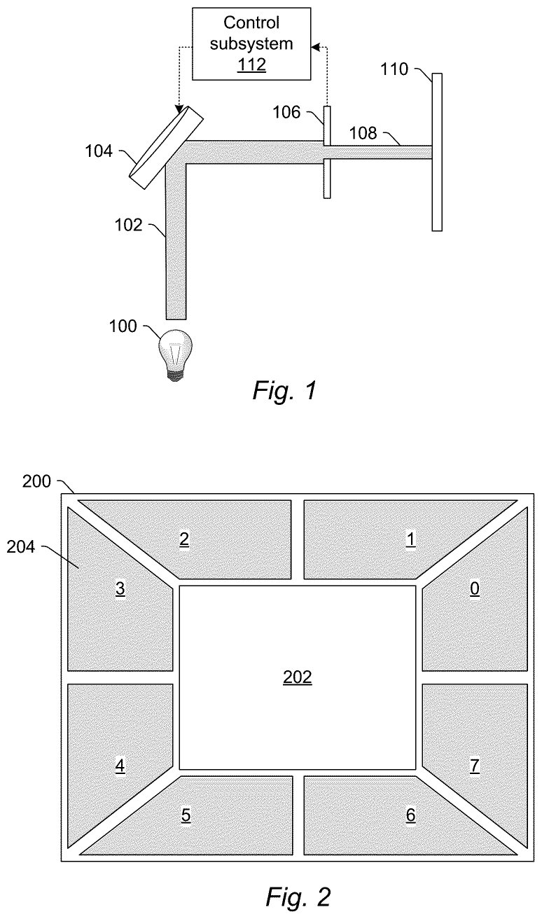

One embodiment of a system configured for determining one or more characteristics of light in an optical system is shown in FIG. 1. The system includes a detector positioned in a path of light between a light source in the optical system and a specimen for which the optical system performs a process. In other words, the detector may be inserted inline with an optical beam that requires stabilization. For example, light source 100 may be configured to generate light 102. The light source may include any of the light sources described further herein configured to generate any of the light described further herein. For example, in one embodiment, the light from the light source has one or more wavelengths shorter than 190 nm.

Light from the light source may be directed to optical element 104, which may be, for example, a beam steering optic coupled to an actuator (not shown). Although optical element 104 is shown in FIG. 1 as a single, reflective optical element, in practice, optical element 104 may include any suitable number and configuration of reflective and/or other optical elements. Detector 106 is positioned in a path of the light from optical element 104 and beam 108 transmitted by the detector may be incident on specimen 110. As described further herein, the system may include a number of additional optical elements (not shown in FIG. 1) including optical elements that are configured to direct the light transmitted by detector 106 to specimen 110.

The detector includes a center cut-out configured to allow only a first portion of the light from the light source to pass therethrough. For example, as shown in FIG. 1, the beam of light 102 directed to detector has a greater cross-section than light 108 that is transmitted by the detector, indicating that not all of the light incident on the detector is transmitted by the detector. In addition, as shown in cross-section in FIG. 2, detector 200 includes center cut-out 202 configured to allow only a first portion of the light from the light source to pass therethrough. In particular, the center cut-out may transmit nearly all of the light directed to the center cut-out (all of the light directed to the center cut-out except perhaps for a substantially negligible portion of the light that may be diffracted or scattered out of the path of the light beam by the edges of the center cut-out) while, as described further herein, the portion of the detector surrounding the center cut-out may not transmit any of the light incident thereon. The detector shown in FIG. 2 indicates a square or rectangular sensor shape with a square or rectangular cut-out, but other shapes such as circles, ovals, or octagons could also be used in principle for either (or both) of these features.

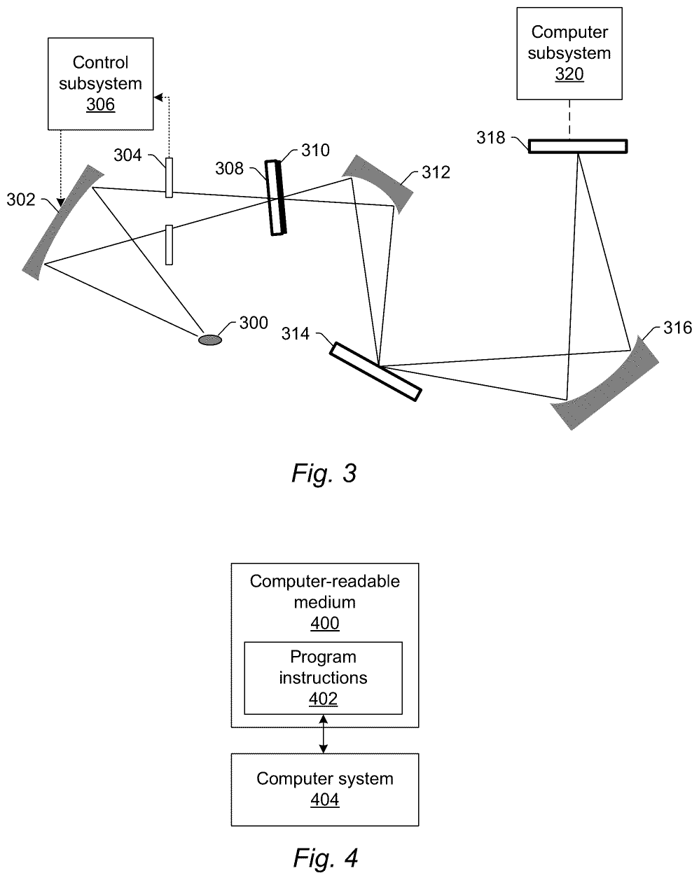

The first portion of the light is directed to the specimen by the optical system during the process. For example, as described further herein, the portion of the light that is transmitted by the center cut-out may be directed to the specimen, possibly by one or more additional elements positioned downstream of the detector. Examples of such additional elements are shown in FIG. 3. Therefore, the first portion of the light transmitted through the center cut-out is the light utilized by the optical system for determining one or more characteristics of the specimen. As such, the beam of light that illuminates the specimen passes through the detector as shown in FIGS. 1 and 3. Such a configuration of the detector and its center cut-out is important since as described further herein, this center cut-out configuration enables the detector to be used for in-situ determination of the illumination beam characteristics, particularly for wavelengths for which no partially transmissive optical elements currently exist.

In one embodiment, the first portion is greater than a majority of the light and less than all of the light. For example, the detector embodiments described herein are different from currently used quad-cell beam position sensors to allow transmission of the majority of the beam power through the center cut-out. Since the first portion of the light transmitted by the center cut-out of the detector is used as the illumination beam by the optical system, the center cut-out is preferably configured to transmit as much of the beam as possible while being small enough so that enough of the light beam is incident on the detector segments as described further herein. Therefore, the dimensions of the center cut-out as well as other characteristics such as shape may be determined based on the known or expected parameters of the optical system and particularly those that affect the characteristics of the illumination beam.

In general, “greater than a majority of the light and less than all of the light” as that phrase is used herein may be defined by a range of percentages of the cross-section of the beam that is transmitted by the center cut-out, and appropriate ranges for the detectors described herein may be, for example, greater than 50% and less than 95% of the light. Other numerical ways of quantifying “greater than a majority of the light and less than all of the light” may also be used such as fractions. In addition, although the first portion may be defined based on dimensions of the cross-section of the light that is transmitted by the center cut-out versus the total dimensions of the cross-section of the light directed to the detector, the first portion may be defined based on other characteristics of the light such as power.

In another embodiment, the center cut-out is configured to allow the first portion of the light to pass therethrough without any attenuation of power of the first portion of the light. For example, the center cut-out is preferably configured to allow unattenuated transmission of the primary beam such that only the beam periphery is blocked. This is an essential design feature for maximizing power transmission through systems that operate at wavelengths for which efficient beam splitters do not yet exist such as EUV (e.g., 13.5 nm). In this manner, the center cut-out may be an actual opening in the detector, meaning that no optical element that acts upon the light is positioned in the center cut-out of the detector. More specifically, because no refractive optical elements currently exist for wavelengths described herein, the center cut-out is preferably simply an opening in the detector whose characteristics are determined as described further herein. Therefore, the embodiments described herein can be advantageously used to provide servo control feedback for moving a mirror (or other element of the system) to stabilize beam pointing in an EUV or soft X-ray beam line without attenuating any power within the center transmitted region of the beam.

The embodiments described herein can also be used for wavelengths other than those described herein. However, for wavelengths of light for which refractive optical elements exist, e.g., wavelengths above 190 nm, a partially reflective beam splitter that directs some of the light to a traditional qual-cell detector (i.e., without a hole like the center cut-out described herein) would be better suited to such systems since such detectors can capture the whole shape and possibly other characteristics of the beam rather than just the edges as described herein. Therefore, the embodiments described herein are particularly suited for the wavelengths described herein (e.g., below 190 nm) for which no suitable beam splitters currently exist and even for electron or ion beams since these beams also cannot be split in the same way that light above the 190 nm wavelength can.

The detector also includes four or more detector segments positioned around the center cut-out and in a path of only a second portion of the light from the light source. The four or more detector segments are configured to separately generate output responsive to the light incident thereon. In this manner, the detector may be referred to as a segmented detector. In addition, although the detector is shown in FIG. 2 as an eight-segmented detector with a center cut-out, the detector may include only four segments or more than four segments depending on the one or more characteristics that are to be determined from the output separately generated by each of the segments. For example, if the detector is only to be used to determine spatial characteristic(s) of the light, then the detector may include only four segments. However, if the detector is to be used to determine spatial characteristic(s), possibly in combination with shape characteristic(s), then more than four detector segments may be included in the detector.

Each of the detector segments may be configured as any suitable detector elements such as two-dimensional (2D) detectors, charge coupled devices (CCD cameras), time delay integration (TDI) cameras, etc. In this manner, the detector segments may each detect light as a function of position within the image plane of the detector. Other types of detectors may be used as well. For example, position sensitive detector(s) and photomultiplier tubes (PMTs) may be used as the detector segments.

The detector segments may also include non-imaging detectors or imaging detectors. If the detector segments are non-imaging detectors, each of the detector segments may be configured to detect certain characteristics of the light such as intensity but may not be configured to detect such characteristics as a function of position within the imaging plane. As such, the output that is generated by each of the detector segments may be signals or data, but not image signals or image data. However, in other instances, the detector segments may be configured as imaging detectors that are configured to generate imaging signals or image data. Therefore, the detector segments may be configured to generate output and/or images described herein in a number of ways.

In one embodiment, the second portion of the light is approximately equal to a minimum amount of the light required for determining the one or more characteristics. For example, as described above, the center cut-out of the detector transmits light that is used to illuminate the specimen during a process. Therefore, the detector is preferably configured such that the center cut-out transmits the maximum amount of light while the detector segments block and detect only the amount of light needed to accurately characterize the illumination light beam. In this manner, the detector preferably maximizes the amount of light available for specimen illumination while ensuring that sufficient light is available for detection of the light characteristic(s). The second portion of the light may be “approximately equal” to the minimum amount of the light required for the light characteristic determination in that once the minimum amount of the light required for the light characteristic determination is determined, that minimum amount may optionally be adjusted, e.g., by +/−1%, for practical implementation or other considerations. In other words, the second portion of the light does not have to exactly equal the minimum amount of the light required for determining the one or more characteristics of the light, but the second portion of the light is preferably minimized as much as possible to maximize the light available for specimen illumination while also allowing enough light to be detected for light beam characterization.

In another embodiment, the first and second portions of the light are mutually exclusive. In a further embodiment, the four or more detector segments are configured to block the second portion of the light from reaching the specimen. For example, the center cut-out is sized to allow unattenuated transmission of the beam center while a fraction of the beam periphery is blocked and detected by the detector segments. In this manner, the detector is configured so that the center cut-out transmits 100% of the light directed thereto while the other portions of the detector, e.g., the detector segments and any material on which they are formed, fabricated, or coupled, do not transmit any of the light incident thereon. In other words, no part or portion of the detector is partially transmissive for the light for which the detector is configured. As such, (substantially) all of the first portion of the light is transmitted by the detector center cut-out while all of the second portion is blocked by the detector segments. Therefore, the detector prevents a portion of the beam from illuminating the specimen during use, but as described further herein, the detector may be configured to minimize the reduction in beam power that is available for specimen illumination.

In an additional embodiment, the detector is positioned in the path of the light between the light source and the specimen while the optical system is detecting the light from the specimen during the process to thereby determine information for the specimen. For example, the detector may be configured as a segmented detector, e.g., an octa-cell detector, with center transmissive cut-out, that can be placed inline with an optical beam for in-situ measurements of beam position and/or shape. A primary purpose of the detector may be to provide servo control feedback for beam stabilization in which an optic, mounted on an actuator, is moved to maintain desired beam pointing based on measured position. In addition, by blocking and sampling only a substantially small fraction of the beam power on the periphery of the beam (e.g., a minimum amount required for measurement purposes) while also transmitting the center of the beam power unattenuated, the detector can be used to monitor the beam characteristics (e.g., position and/or shape) while the process is performed on the specimen. In other words, by utilizing only a minimal, peripheral portion of the illumination beam, the detector can monitor the illumination beam characteristics without interfering with the primary system function (e.g., specimen inspection, metrology, defect review, etc.).

In a further embodiment, the detector is configured to have a fixed positioned in the optical system during use. For example, the center cut-out configuration allows the detector to be positioned in the path of the light between the light source and the specimen for the duration of the process performed on the specimen. In other words, since partially transmissive beam splitters do not yet exist for the wavelengths of light described herein, any beam measurement device (a detector or an element that directs light to a detector) without a 100% transmissive section like the detectors described herein would have to be moved into the path of the light for measurement of the beam characteristics and then moved out of the path of the light so that the specimen can be examined with the light. However, the embodiments described herein can be used for beam measurements (e.g., position and/or shape) without shuttling the device into and out of the beam path. This capability reduces the cost, complexity, and contamination risk of the system compared to those requiring device movement, which is particularly valuable in ultra-clean and/or space-constrained environments.

Although the detector preferably has a fixed position during use, the system may be configured to alter a position of the detector between uses. For example, the position of one or more elements of the system, possibly including the detector embodiments described herein, may be changed in response to intentional changes in the beam position (e.g., for different process set ups, for calibration, etc.). The system may be configured for altering any positions of the elements of the system, including the detector embodiments described herein, in any suitable manner known in the art.

In addition to having a fixed position during use, the detector segments may also have a fixed position with respect to the detector, particularly when the detector is a single piece of fabricated semiconductor. Therefore, each of the detector segments will also have a fixed position with respect to the light beam and the system during use. In this manner, the configuration of the center cut-out and the detector segments will generally not change during use or during the lifetime of the detector. However, for systems that are configured for different beam diameters, it may be desirable to configure the detector so that the detector segments can be moved toward and away from the center cut-out to accommodate different beam diameters (e.g., to ensure that a majority of the beam is transmitted by the center cut-out and to ensure that the periphery of the beam is incident on the detector segments). In this manner, if there is a change in the beam diameter, the position of the detector segments can be adjusted accordingly. Even if the detector segments can be moved with respect to the detector, in general, it would be advantageous for their positions to be fixed during use for the same reasons described further herein. Configuring the detector so that individual segments can be moved with respect to the detector will increase the complexity and cost of the detector, and so such configurations may only be implemented when relatively substantial changes in the beam diameter are anticipated.

Although a detector that is a single piece of fabricated semiconductor may be a particularly advantageous way to implement the detector described herein, the detector may actually include physically separate detector segments. For example, each of the detector segments may be different pieces of fabricated semiconductor. In another example, two of the detector segments may be a first, single piece of fabricated semiconductor, and another two of the detector segments may be a second, single piece of fabricated semiconductor. In this manner, each of the different detector segments, in of themselves, may not have a center cut-out, but in combination through their relative positions to each other, they may form a center cut-out in the overall detector. In some such embodiments then, the center cut-out may be formed not in a single piece of fabricated semiconductor, but by the relative positions of the detector segments to each other. Therefore, by positioning the different detector segments in different positions relative to each other, various characteristics of the center transmissive portion of the overall detector (the combination of different detector segments) may be altered. Those characteristics may include, but are not limited to, shape and dimensions.

When the different detector segments are formed of different pieces of material(s), the different detector segments may be mounted in the system as described further herein, e.g., so that their positions are fixed during use, even if they can be moved between uses. Furthermore, when the different detector segments are formed of different pieces of material(s), the different detector segments do not necessarily have to be positioned in the same plane along the optical path. Instead, the different detector segments may have different positions along the optical path (i.e., different planes along the optical path or one detector segment may be downstream of another detector segment) while still being configured as described further herein. For example, one detector segment may be positioned to detect one portion of the light at one position in the light path, another detector segment may be positioned to detect another portion of the light at another position in the light path that is slightly downstream of the first detector segment, and the positions of the two detector segments relative to each other may define at least part of the boundary of the center cut-out of the detector. The same configuration may be implemented when more than two detector segments are formed in one piece of material like a bi-cell detector element that contains two of the detector segments described herein. In some such examples, the different detector segments may not be located in the same plane along the optical path to allow for things like an appropriate clearance between the different pieces of material from which the different detector segments are formed. In addition, it may be most practical in such situations to have the different detector segments located as close to each other as possible along the optical path of the illumination beam, but any appropriate positions of the detector segments along the beam may be used.

The system also includes a control subsystem configured for determining one or more characteristics of the light from the light source based on the output separately generated by the four or more detector segments. Therefore, the embodiments described herein may use the output separately generated by the different segments of the detector to determine one or more characteristics of the light as described further herein. For example, as shown in FIG. 1, the system may include control subsystem 112 coupled to detector 106. The control subsystem may include one or more computer subsystems and possibly other elements such as firmware, a servo loop, and any other suitable controller type elements known in the art.

Control subsystem 112 may be coupled to detector 106 in any suitable manner (e.g., via one or more transmission media, which may include “wired” and/or “wireless” transmission media) such that the control subsystem can receive the output, images, etc. generated by detector 106. Control subsystem 112 may be configured to perform a number of functions using the output of the detector as described herein and any other functions described further herein. This control subsystem may be further configured as described herein.

The control subsystem may include one or more computer subsystems (not shown) that are configured to perform one or more functions such as determining the one or more characteristics of the light from the detector segment outputs. The computer subsystem(s) of the control subsystem (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer subsystem, then the different computer subsystems may be coupled to each other such that images, data, information, instructions, etc. can be sent between the computer subsystems as described further herein. For example, a computer subsystem of control subsystem 112 may be coupled to computer subsystem 320 shown in FIG. 3 by any suitable transmission media (not shown), which may include any suitable wired and/or wireless transmission media known in the art. Two or more of such computer subsystems may also be effectively coupled by a shared computer-readable storage medium (not shown).

In one embodiment, the one or more characteristics include one or more spatial characteristics of the light. For example, measurements for control and alignment purposes can be gained by comparing the ratios of incident power detected on each (or at least more than one) segment. Power imbalances on the left vs. right and top vs. bottom segments provide position feedback, which can be used for controlling a beam stabilization actuator. In one such embodiment shown in FIG. 2, detector 200 includes 8 segments 204 labeled 0 to 7 and positioned around center cut-out 202. In the following equations, then, S₀ stands for the output of segment 0, S₁ stands for the output of segment 1, and so on. The beam position in the x direction, Sₓ, may then be determined using the following equation:

$${S}_{x} = \frac{( {S}_{0} + {S}_{1} + {S}_{6} + {S}_{7} ) - ( {S}_{2} + {S}_{3} + {S}_{4} + {S}_{5} )}{{Σ}_{i = 0}^{7} {S}_{i}}$$

The beam position in the y direction, S_{y}, may be determined using the following equation:

$${S}_{y} = \frac{( {S}_{0} + {S}_{1} + {S}_{2} + {S}_{3} ) - ( {S}_{4} + {S}_{5} + {S}_{6} + {S}_{7} )}{{Σ}_{i = 0}^{7} {S}_{i}}$$

Similar equations can be used to determine the positions in the x and y directions for detectors having different numbers of segments than that shown in FIG. 2. In addition, although the equations described above provide a quick, easy, and accurate way to determine the beam position from the detector segment outputs, any other method, algorithm, or function may be used to determine the beam position from the detector segment outputs. An appropriate method, algorithm, or function may be selected or determined based on the configuration of the detector and/or the beam position characteristics that are to be determined using the detector segment outputs.

In another embodiment, the four or more detector segments include six or more detector segments, the one or more characteristics include one or more spatial characteristics and one or more shape characteristics of the light, and the control subsystem is configured for simultaneously determining the one or more spatial characteristics and the one or more shape characteristics based on the output separately generated by the six or more detector segments. For example, beam position detection may be performed using a quad-cell detector, but the inclusion of more than four, e.g., six, eight, or even more segments, allows for simultaneous measurement of beam shape, which can serve a number of diagnostic purposes such as guiding upstream optical alignment. In this manner, the embodiments described herein may include a detector configured as an octa-cell detector, and octa-cell detector metrics may be used for servo loop closure and evaluation of beam quality. In addition, utilizing more than four segments (e.g., 8) rather than just four segments enables simultaneous, in-situ measurement of beam position and beam aberration within a single device.

In one such embodiment, the one or more shape characteristics include beam aberration. In another embodiment, the one or more shape characteristics include anisotropy in the light. In a further embodiment, the one or more shape characteristics include one or more characteristics of multi-pole components of the light. For example, ratios other than those described above can be used to measure anisotropy in the beam profile (e.g., elliptical vs. circular) and two hexapole and two octupole components. Referring back to the sensor shown in FIG. 2, the control subsystem may be configured to determine beam symmetry or astigmatism using the following two equations.

$${S}_{s tig , A} = \frac{( {S}_{1} + {S}_{2} + {S}_{5} + {S}_{6} ) - ( {S}_{0} + {S}_{3} + {S}_{4} {+}_{7} )}{{Σ}_{i = 0}^{7} {S}_{i}}$$

$${s}_{stig , B} = \frac{( {S}_{0} + {S}_{1} + {S}_{4} + {S}_{5} ) - ( {S}_{2} + {S}_{3} + {S}_{6} + {S}_{7} )}{{Σ}_{i = 0}^{7} {S}_{i}}$$

These equations can be easily modified to determine the beam symmetry for detectors having different numbers of segments than that shown in FIG. 2. In addition, although the equations described above provide a quick, easy, and accurate way to determine some beam shape characteristics from the detector segment outputs, any other method, algorithm, or function may be used to determine the beam shape characteristics from the detector segment outputs. An appropriate method, algorithm, or function may be selected or determined based on the configuration of the detector and/or the beam shape characteristics that are to be determined using the detector segment outputs.

In addition to the position and shape characteristics described herein, the detector may be configured to also or alternatively monitor one or more other characteristics of the illumination beam. Such characteristics include, but are not limited to, wavelength, intensity, temporal characteristics, size, and rotational shape. For example, monitoring the light characteristics as described herein may enable correction for variation of the illumination beam in temporal and spatial domains. In such a configuration, the detector may generate output at different points in time (whether that is intermittently or continuously) and at different points in time relative to the illumination of the specimen (e.g., prior to illumination of the specimen, during illumination of the specimen, and/or after illumination of the specimen). More specifically, because the detector can generate output responsive to the illumination light beam without affecting the performance of the optical system, the detector may generate output that is responsive to both time and spatial characteristics of the light. That configuration enables the control subsystem to determine the spatial and temporal characteristic(s) of the light from the detector segment outputs, which can then be used to determine both spatial and temporal changes to one or more parameters of the optical system as described further herein.

The configuration of the detector may vary depending on the light characteristics that are to be determined using the detector segment outputs. For example, if the detector is configured for detecting the wavelength characteristics of the light, the detector segments are preferably configured for generating output responsive to different wavelengths of light. Such a detector configuration would most likely increase the cost and complexity of the detector compared to a wavelength insensitive detector. Therefore, the detector may be configured to detect only the light characteristics for which it will be used to avoid unnecessarily complicating and increasing the cost of the detector.

In one embodiment, the control subsystem is configured for altering one or more parameters of the optical system based on the determined one or more characteristics. For example, control subsystem 112 shown in FIG. 1 may include firmware (not shown) and a servo loop (not shown). The firmware and servo loop may have any suitable configuration known in the art suitable for comparing the determined one or more characteristics to a predetermined range of values for the determined one or more characteristics and then altering a parameter of at least one of the light source, one or more optical elements, and/or one or more other detectors in response thereto. In one such example, the one or more determined characteristics may include beam position information, and the control subsystem may be configured for altering the one or more parameters of the optical system by applying corrections to optical element 104 based on any unacceptable variation in the beam position.

The parameter(s) of the optical system that are altered by the control subsystem may include any parameter that can cause a change in the characteristic(s) of the light at one or more planes in the optical system, which may vary depending on the configuration of the optical system. For example, although the control subsystem is shown to alter parameter(s), e.g., a position, of optical element 104 in FIG. 1 and optical element 302 in FIG. 3, the control subsystem may be configured to alter one or more parameters of any other elements in the system. In one such example, the position of optical element 312 shown in FIG. 3 may be altered in response to the position of the beam measured by detector 304. In another such example, rather than steering a mirror in response to the characteristic(s) of the illumination beam, the control subsystem may be configured for controlling one or more actuators to move the entire platform or chamber to which the mirror or light source is attached. The alterations to the parameter(s) of the optical system may be determined in any suitable manner using any suitable type of control loop, algorithm, method, function, etc.

The parameter(s) of the optical system that are altered by the control subsystem may also include any parameter of any element that performs a function or step using output of the detector(s) of the optical system. For example, the parameter(s) that are altered may include one or more parameters of a computer subsystem (e.g., computer subsystem 320 shown in FIG. 3) or one or more parameters of a method, step, algorithm, process, etc. performed by the computer subsystem on the output generated by one or more first detectors 318. Such parameter(s) may include, for example, parameter(s) of image processing performed to correct the images generated by the first detector(s) for any variations in the light source. In one such example, the determined one or more characteristics of the light may be spatial and temporal characteristics in the brightness of the light at the specimen plane. If such characteristic(s) show temporal changes, the control subsystem may determine one or more corrections to specimen images that can be made in the image processing performed by the computer subsystem to mitigate any effects that the temporal changes have on the specimen images. Therefore, the one or more parameters of the optical system that are controlled in response to the determined characteristic(s) may be optical parameters and/or image processing parameters.

In another embodiment, the control subsystem is configured for outputting the determined one or more characteristics to a computer subsystem of the optical system, and the computer subsystem is configured for altering one or more parameters of the optical system based on the determined one or more characteristics. For example, the control subsystem itself may not necessarily determine corrections and/or alterations to the optical system. Instead, the control subsystem may simply output the determined one or more characteristics in any suitable manner and in any suitable format to another system or method such as computer subsystem 320 shown in FIG. 3 that determines alterations to one or more parameters of the optical system based on the determined one or more characteristics and alters the one or more parameters based on that determination. In other words, the control of the optical system based on the determined one or more characteristics of the light may be distributed across multiple subsystems such as the control subsystem and a computer subsystem. However, the control subsystem may also be part of the computer subsystem or vice versa so that one subsystem both determines the characteristic(s) of the light and alters one or more parameters of the optical system based on the characteristic(s). The computer subsystem may alter the one or more parameters of the optical system as described further herein.

In a further embodiment, the control subsystem or a computer subsystem is configured for altering one or more parameters of the optical system based on the determined one or more characteristics, and the one or more parameters include one or more parameters of a movable optical element in the optical system configured to control a position of the light on the specimen. For example, regardless of which subsystem actually alters the one or more parameters of the optical system, the embodiments described herein can provide position feedback for servo control of an element such as beam steering optic 104, which may be performed via an actuator (not shown) coupled to the optic. Therefore, the embodiments described herein can be operated to close a beam stabilization servo loop using multi-cell (e.g., octa-cell) detector feedback with unattenuated transmission of the beam center.

Another embodiment of a system configured for determining one or more characteristics of light in an optical system is shown in FIG. 3. The system includes light source 300 configured for generating light having one or more wavelengths shorter than 190 nm. The light source may be configured as described further herein.

The system also includes optical elements configured for directing the light generated by the light source to a specimen and directing the light from the specimen to one or more first detectors configured to generate first output responsive to the light from the specimen. In this manner, the system may include elements configured for illuminating the specimen and detecting light from the specimen. In the embodiment shown in FIG. 3, the optical elements include optical elements 302, 312, and 316, and possibly homogenizer 308. Optical element 302 is configured to collect light from light source 300 and to direct the light to detector 304 and through optional homogenizer 308, positioned at intermediate field plane 310. Optical element 312 is configured for directing the light transmitted by detector 304 and possibly optional homogenizer 308 to specimen 314. Light from specimen 314 is collected by optical element 316 that directs the light from the specimen to one or more first detectors 318.

As shown in FIG. 3, detector 304 is positioned in front of (or upstream of) homogenizer 308. In general, for any system that includes a homogenizer, the detector embodiments described herein would be positioned upstream of the homogenizer. Therefore, the detector should generally be positioned between the optical element(s) that are responsible for beam positioning (and possibly other beam characteristics), e.g., optical element 302, and the homogenizer. However, for systems that do not include a homogenizer, the detector embodiments described herein can be positioned in other locations in the illumination beam path (e.g., between optical element 312 and specimen 314). In systems without homogenizers, the detector embodiments described herein may also be positioned in the path of the light from the specimen. This detector positioning may require more complicated calculations (to account for effects of the specimen on the illumination beam) than if the detector is positioned upstream of the specimen, but it is another possibility.

The embodiments described herein may also include more than one beam position and/or shape detector configured as described herein. For example, one detector may be positioned in the illumination path and another may be positioned in the collection/detection path. The benefit of measuring beam position and/or shape at multiple points in the system should be weighed against the loss of peripheral beam power that increases with each added detector.

Although each of optical elements 302, 312, and 316 is shown in FIG. 3 as a single, concave reflective optical element, each of these optical elements may include any suitable number of optical elements having any suitable configuration. Optional homogenizer 308 may also have any suitable configuration known in the art.

The angle(s) at which optical element 302 collects light from the light source may vary depending on the characteristics of the light source, characteristics of the specimen, and the purpose of specimen illumination. In addition, the angle(s) at which optical element 312 directs light to specimen 314 may vary based on similar variables. For example, the system may be configured for illuminating specimen 314 with light at different angles depending on if the system is configured for inspection, metrology, or defect review.

Furthermore, the angle(s) at which optical element 316 collects light from specimen 314 and directs or images the light to one or more first detectors 318 may vary depending on the characteristics of the specimen and the light directed to it for illumination, which will affect the characteristics of the light from the specimen, and the configuration of the system such as what kind of light (e.g., scattered, specularly reflected, etc.) is being directed to the one or more first detectors. The light from the specimen that is collected by the optical elements may include scattered light, specularly reflected light, diffracted light, etc., or some combination thereof.

The system may also include a scanning subsystem (not shown) configured to cause the light to be scanned over the specimen. For example, the system may include a stage (not shown) on which specimen 314 is disposed. The scanning subsystem may include any suitable mechanical and/or robotic assembly (that includes the stage) that can be configured to move the specimen such that the light can be scanned over the specimen. In addition, or alternatively, the system may be configured such that the one or more optical elements perform some scanning of the light over the specimen. The light may be scanned over the specimen in any suitable fashion.

The one or more first detectors may include any suitable detectors known in the art including those described herein. In general, the one or more first detectors may be imaging detector(s) such as CCD cameras or TDIs although non-imaging detectors may also be used. In addition, although first detector(s) 318 are shown in FIG. 3 as a single detector, the first detector(s) may include any suitable number of detector(s), e.g., 1 detector, 2 detectors, 3 detectors, etc., each of which may be configured the same or differently. If the first detector(s) include more than one detector, each of the detectors may be positioned in the same image plane but at different positions within the image plane so as to separately detect different portions of the light directed to the image plane. Such configurations of more than one first detector may be determined based on, for example, the dimensions of the illuminated field in the imaging plane, the characteristics of the specimen, and the configuration of the first detector(s).

It is noted that FIGS. 1 and 3 are provided herein to generally illustrate some configurations of optical elements and detectors that may be included in the system embodiments described herein. Obviously, the optical element and detector configurations described herein may be altered to optimize the performance of the system as is normally performed when designing a commercial system. In addition, the systems described herein may be implemented using an existing optical system (e.g., by adding the segmented detector and other functionality described herein to an existing optical system) such as the RAPID 7xxx systems, which are commercially available from KLA Corp., Milpitas, Calif. For some such systems, the embodiments described herein may be provided as optional functionality of the existing system (e.g., in addition to other functionality of the system). Alternatively, the system described herein may be designed “from scratch” to provide a completely new system.

The system shown in FIG. 3 also includes second detector 304 positioned in a path of the light between light source 300 and specimen 314. The second detector may be configured as described further herein. For example, the second detector includes center cut-out 202 shown in FIG. 2 configured to allow only a first portion of the light from the light source to pass therethrough. The first portion of the light is directed to the specimen by one or more of the optical elements (e.g., optical element 312 shown in FIG. 3). The center cut-out and the first portion of the light may be configured as described further herein. The second detector also includes four or more detector segments 204 shown in FIG. 2 positioned around the center cut-out and in a path of a second portion of the light from the light source. The four or more detector segments are configured to separately generate second output responsive to the light incident thereon. The four or more detector segments may be configured as described further herein.

The system further includes control subsystem 306 shown in FIG. 3 configured for determining one or more characteristics of the light from the light source based on the second output and for altering at least one of one or more parameters of light source 300, one or more parameters of the optical elements (e.g., one or more of optical elements 302, 312, and 316), one or more parameters of one or more first detectors 318, and one or more parameters used by computer subsystem 320 to determine the information based on the determined one or more characteristics. The control subsystem may be configured for determining the one or more light characteristics and altering at least one parameter of the optical system as described further herein.

In one embodiment, the specimen is a reticle. The reticle may include any reticle known in the semiconductor arts including any reticle that is configured for use in a VUV lithography process, an EUV lithography process, or a soft x-ray lithography process. The reticle may also be a reticle for use in another lithography process (e.g., 193 nm lithography), when there is some advantage to performing one of the processes described herein (e.g., inspection, metrology, defect review) at a wavelength less than 190 nm. In another embodiment, the specimen is a wafer. The wafer may include any wafer known in the semiconductor arts. The embodiments are also not limited in the specimen for which they can be used. For example, the embodiments described herein may be used for specimens such as flat panels, personal computer (PC) boards, and other semiconductor specimens.

The system further includes computer subsystem 320 configured for determining information for the specimen based on the first output. The computer subsystem may be configured for determining the information in a number of different ways depending on, for example, the specimen, the optical system configuration, and the information being determined for the specimen. For example, in one embodiment, the optical system is configured as an inspection system. Such an optical system may be configured for generating output that is suitable for detecting defects on the specimen. In such an embodiment, computer subsystem 320 may be configured for detecting defects on specimen 314 by applying a defect detection method to the output generated by first detector(s) 318. Computer subsystem 320 may be coupled to first detector(s) 318 as described further herein so that it can receive the output generated by the first detector(s). Detecting defects on the specimen may be performed in any suitable manner known in the art (e.g., applying a defect detection threshold to the output and determining that any output having a value above the threshold corresponds to a defect (or a potential defect)) with any suitable defect detection method and/or algorithm.

If the specimen that is being inspected is a reticle, the wavelength(s) of light used to illuminate the reticle may be the same as the wavelength(s) of light that the reticle will be used with in a lithography process. In other words, the inspection system may be configured as an actinic reticle inspection system although it may also or alternatively be configured for non-actinic reticle inspection. In embodiments in which the optical system is configured for inspection, the embodiments may be further configured as described in U.S. Patent Application Publication Nos. 2010/0165310 by Sewell et al. published Jul. 1, 2010, 2015/0192459 by Kvamme published Jul. 9, 2015, 2015/0253658 by Terasawa et al. published Sep. 10, 2015, and 2019/0331611 by Ebstein published Oct. 31, 2019, which are incorporated by reference as if fully set forth herein. The embodiments described herein may be further configured as described in these publications.

In another embodiment, the optical system is configured as a metrology system. In a further embodiment, the optical system is configured as a defect review system. For example, the embodiment of the system shown in FIG. 3 may be modified in one or more parameters to provide different imaging capability depending on the application for which it will be used. In one such example, the optical system may be configured to have a higher resolution if it is to be used for metrology rather than for inspection. In other words, the embodiment of the optical system shown in FIG. 3 describes some general and various configurations for an optical system that can be tailored in a number of manners that will be obvious to one skilled in the art to produce systems having different imaging capabilities that are more or less suitable for different applications.

In this manner, the optical system may be configured for generating output that is suitable for re-detecting defects on the specimen in the case of a defect review system and for measuring one or more characteristics of the specimen in the case of a metrology system. In a defect review system embodiment, computer subsystem 320 may be configured for re-detecting defects on specimen 314 by applying a defect re-detection method to the output generated by first detector(s) 318 and possibly determining additional information for the re-detected defects using the output generated by the first detector(s). In a metrology system embodiment, computer subsystem 320 may be configured for determining one or more characteristics of specimen 314 using the output generated by the first detector(s). In both cases, computer subsystem 320 may be coupled to first detector(s) 318 as described further herein so that it can receive the output generated by the first detector(s).

Defect review typically involves re-detecting defects detected as such by an inspection process and generating additional information about the defects at a higher resolution, e.g., using the optical system described herein in a high magnification mode. Defect review is therefore performed at discrete locations on the specimen where defects have been detected by inspection. The higher resolution data for the defects generated by defect review is generally more suitable for determining attributes of the defects such as profile, roughness, more accurate size information, etc. Computer subsystem 320 may be configured to determine such information for defects on the specimen in any suitable manner known in the art.

Metrology processes are used at various steps during a semiconductor manufacturing process to monitor and control the process. Metrology processes are different than inspection processes in that, unlike inspection processes in which defects are detected on a specimen, metrology processes are used to measure one or more characteristics of the specimen that cannot be determined using currently used inspection tools. For example, metrology processes are used to measure one or more characteristics of a specimen such as a dimension (e.g., line width, thickness, etc.) of features formed on the specimen during a process such that the performance of the process can be determined from the one or more characteristics. In addition, if the one or more characteristics of the specimen are unacceptable (e.g., out of a predetermined range for the characteristic(s)), the measurements of the one or more characteristics of the specimen may be used to alter one or more parameters of the process such that additional specimens manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a specimen may be independent of the results of an inspection process performed on the specimen. In particular, the locations at which a metrology process is performed may be selected independently of inspection results. In addition, since locations on the specimen at which metrology is performed may be selected independently of inspection results, unlike defect review in which the locations on the specimen at which defect review is to be performed cannot be determined until the inspection results for the specimen are generated and available for use, the locations at which the metrology process is performed may be determined before an inspection process has been performed on the specimen. Computer subsystem 320 may be configured to determine any suitable characteristics for the specimen in any suitable manner known in the art.

In any of the system embodiments described herein, computer subsystem 320 shown in FIG. 3 may be configured to generate results that include at least the information determined for the specimen based on the output generated by the first detector(s) possibly with any other output generated by the computer subsystem. The results may have any suitable format (e.g., a KLARF file, which is a proprietary file format used by tools commercially available from KLA, a results file generated by Klarity, which is a tool that is commercially available from KLA, a lot result, etc.). In addition, all of the embodiments described herein may be configured for storing results of one or more steps of the embodiments in a computer-readable storage medium. The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc. to perform one or more functions for the specimen or another specimen.

Such functions include, but are not limited to, altering a process such as a fabrication process or step that was or will be performed on the specimen in a feedback, feedforward, in-situ manner, etc. For example, the computer subsystem may be configured to determine one or more changes to a process that was or will be performed on the specimen based on the detected defect(s) and/or other determined information. The changes to the process may include any suitable changes to one or more parameters of the process. For example, if the determined information is defects detected on the specimen, the computer subsystem preferably determines those changes such that the defects can be reduced or prevented on other specimens on which the revised process is performed, the defects can be corrected or eliminated on the specimen in another process performed on the specimen, the defects can be compensated for in another process performed on the specimen, etc. The computer subsystem may determine such changes in any suitable manner known in the art.

Those changes can then be sent to a semiconductor fabrication system (not shown) or a storage medium (not shown in FIG. 3) accessible to both the computer subsystem and the semiconductor fabrication system. The semiconductor fabrication system may or may not be part of the system embodiments described herein. For example, the systems described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

The embodiments described herein have a number of advantages over other methods and systems for monitoring and controlling light in the wavelength ranges described herein. For example, the embodiments circumvent the disadvantages of currently used detectors by providing a center cut-out such that the detector can be placed directly inline with the primary beam without the use of a beam splitter. Beam position can be measured by blocking/sampling a substantially small fraction of beam power on the periphery of the beam while transmitting the center of the beam unattenuated. By using more than four detector segments (e.g., 8) rather than only four, a measurement of beam shape can be made in-situ while the system is fully operational. Furthermore, this measurement can be obtained on the same device without the added cost, complexity, and contamination risk of shuttling in another beam measurement device such as a tooling camera. This capability is particularly valuable in ultra-clean or space-constrained environments.

Each of the embodiments of the systems described above may be further configured according to any other embodiment(s) described herein.

Another embodiment relates to a computer-implemented method for determining one or more characteristics of light in an optical system. The method includes detecting light in a path between a light source (e.g., light source 300 shown in FIG. 3) in the optical system and a specimen (e.g., specimen 314) for which the optical system performs a process. The detecting includes passing only a first portion of the light from the light source through a center cut-out (e.g., center cut-out 202 shown in FIG. 2) of a detector (e.g., detector 200). The detector may be further configured as described herein. The first portion of the light is directed to the specimen by the optical system during the process. The detecting also includes separately generating output responsive to the light incident on four or more detector segments (segments 204) of the detector positioned around the center cut-out and in a path of only a second portion of the light from the light source. The method also includes determining one or more characteristics of the light from the light source based on the output separately generated by the four or more detector segments.

Each of the steps of the method may be performed as described further herein. The method may also include any other step(s) that can be performed by the system(s) described herein. The steps of the method may be performed by the systems described herein, which may be configured according to any of the embodiments described herein.

An additional embodiment relates to a non-transitory computer-readable medium storing program instructions executable on a computer system for performing a computer-implemented method for determining one or more characteristics of light in an optical system. One such embodiment is shown in FIG. 4. In particular, as shown in FIG. 4, non-transitory computer-readable medium 400 includes program instructions 402 executable on computer system 404. The computer-implemented method may include any step(s) of any method(s) described herein.

Program instructions 402 implementing methods such as those described herein may be stored on computer-readable medium 400. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMD Extension) or other technologies or methodologies, as desired.

Computer system 404 may be configured according to any of the embodiments described herein.

Further modifications and alternative embodiments of various aspects of the invention will be apparent to those skilled in the art in view of this description. For example, methods and systems for determining one or more characteristics of light in an optical system are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A system configured for determining one or more characteristics of light in an optical system, comprising:
a detector positioned in a path of light between a light source in the optical system and a specimen for which the optical system performs a process, wherein the detector comprises:
a center cut-out configured to allow only a first portion of the light from the light source to pass therethrough, wherein the first portion of the light is directed to the specimen by the optical system during the process; and
four or more detector segments positioned around the center cut-out and in a path of only a second portion of the light from the light source, wherein the four or more detector segments are configured to separately generate output responsive to the light incident thereon; and
a control subsystem configured for determining one or more characteristics of the light from the light source based on the output separately generated by the four or more detector segments.

2. The system of claim 1, wherein the first portion is greater than a majority of the light and less than all of the light.

3. The system of claim 1, wherein the second portion of the light is approximately equal to a minimum amount of the light required for determining the one or more characteristics.

4. The system of claim 1, wherein the first and second portions of the light are mutually exclusive.

5. The system of claim 1, wherein the light from the light source has one or more wavelengths shorter than 190 nm.

6. The system of claim 1, wherein the detector is positioned in the path of the light between the light source and the specimen while the optical system is detecting the light from the specimen during the process to thereby determine information for the specimen.

7. The system of claim 1, wherein the detector is configured to have a fixed position in the optical system during use.

8. The system of claim 1, wherein the one or more characteristics comprise one or more spatial characteristics of the light.

9. The system of claim 1, wherein the four or more detector segments comprise six or more detector segments, wherein the one or more characteristics comprise one or more spatial characteristics and one or more shape characteristics of the light, and wherein the control subsystem is further configured for simultaneously determining the one or more spatial characteristics and the one or more shape characteristics based on the output separately generated by the six or more detector segments.

10. The system of claim 9, wherein the one or more shape characteristics comprise beam aberration.

11. The system of claim 9, wherein the one or more shape characteristics comprise anisotropy in the light.

12. The system of claim 9, wherein the one or more shape characteristics comprise one or more characteristics of multi-pole components of the light.

13. The system of claim 1, wherein the center cut-out is further configured to allow the first portion of the light to pass therethrough without any attenuation of power of the first portion of the light.

14. The system of claim 1, wherein the four or more detector segments are further configured to block the second portion of the light from reaching the specimen.

15. The system of claim 1, wherein the control subsystem is further configured for altering one or more parameters of the optical system based on the determined one or more characteristics.

16. The system of claim 1, wherein the control subsystem is further configured for outputting the determined one or more characteristics to a computer subsystem of the optical system, and wherein the computer subsystem is configured for altering one or more parameters of the optical system based on the determined one or more characteristics.

17. The system of claim 1, wherein the control subsystem or a computer subsystem is configured for altering one or more parameters of the optical system based on the determined one or more characteristics, and wherein the one or more parameters comprise one or more parameters of a movable optical element in the optical system configured to control a position of the light on the specimen.

18. The system of claim 1, wherein the light is extreme ultraviolet light.

19. The system of claim 1, wherein the light is vacuum ultraviolet light.

20. The system of claim 1, wherein the light is soft x-rays.

21. The system of claim 1, wherein the optical system is configured as an inspection system.

22. The system of claim 1, wherein the optical system is configured as a metrology system.

23. The system of claim 1, wherein the optical system is configured as a defect review system.

24. A system configured for determining one or more characteristics of light in an optical system, comprising:
a light source configured for generating light having one or more wavelengths shorter than 190 nm;
optical elements configured for directing the light generated by the light source to a specimen and directing the light from the specimen to one or more first detectors configured to generate first output responsive to the light from the specimen;
a computer subsystem configured for determining information for the specimen based on the first output;
a second detector positioned in a path of the light between the light source and the specimen, wherein the second detector comprises:
a center cut-out configured to allow only a first portion of the light from the light source to pass therethrough, wherein the first portion of the light is directed to the specimen by one or more of the optical elements; and
four or more detector segments positioned around the center cut-out and in a path of a second portion of the light from the light source, wherein the four or more detector segments are configured to separately generate second output responsive to the light incident thereon; and
a control subsystem configured for determining one or more characteristics of the light from the light source based on the second output and for altering at least one of one or more parameters of the light source, one or more parameters of the optical elements, one or more parameters of the one or more first detectors, and one or more parameters used by the computer subsystem to determine the information based on the determined one or more characteristics.
